(19) United States
(12) Patent Application Publication
(10) Pub. No.: US 2023/0377767 A1
(43) Pub. Date: Nov. 23, 2023

(54) TRANSPARENT CONDUCTIVE OXIDE THIN FILM AND APPLICATION THEREOF

(71) Applicant: South China University of Technology, Guangzhou (CN)

(72) Inventors: Miao Xu, Guangzhou (CN); Hua Xu, Guangzhou (CN); Min Li, Guangzhou (CN); Jiawei Pang, Guangzhou (CN); Zikai Chen, Guangzhou (CN); Hong Tao, Guangzhou (CN); Jianhua Zou, Guangzhou (CN); Lei Wang, Guangzhou (CN); Junbiao Peng, Guangzhou (CN)

(73) Assignee: South China University of Technology, Guangzhou, Guangdong (CN)

(21) Appl. No.: 18/229,669

(22) Filed: Aug. 2, 2023

Related U.S. Application Data
(63) Continuation of application No. PCT/CN2021/096785, filed on May 28, 2021.

(30) Foreign Application Priority Data
Feb. 3, 2021 (CN) 202110152018.3

(51) Int. Cl. H01B 1/08; H01B 5/14

(52) U.S. Cl. CPC H01B 1/08; H01B 5/14

(57) ABSTRACT

Disclosed is a transparent conductive oxide thin film. The metal oxide is a transparent conductive material of (In₂O₃)ₓ(MO)_{y}(ReO)_{z} formed by doping a small amount of a rare earth oxide ReO into an indium-containing metal oxide MO—In₂O₃ as a photon-generated carrier conversion center. According to the present application, in an indium-based metal oxide, a rare earth oxide material is introduced, such that the carrier concentration is controlled, and the mobility is improved; rare earth ions in the rare earth oxide have the lower electronegativity, and an ionic bond Ln-O formed by the rare earth ions and oxygen ions has the higher bond breaking energy, such that the oxygen vacancy concentration in the In₂O₃ thin film may be effectively controlled. The rare earth ions have the ionic radius equivalent to that of indium ions, defect scattering caused by structure mismatch may be reduced, the high mobility characteristics thereof may be kept better.

### CROSS-REFERENCE TO RELATED APPLICATIONS

The present application is a continuation application of PCT application No. PCT/CN2021/096785 filed on May 28, 2021, which claims the benefit of Chinese Patent Application No. 202110152018.3 filed on Feb. 3, 2021. The contents of all of the aforementioned applications are incorporated by reference herein in their entirety.

### TECHNICAL FIELD

The present application relates to the technical field of film deposition technologies, and specially relates to preparation of transparent conductive metal oxide (TCO) thin films in flat panel displays and solar cells, in particular to a transparent conductive oxide thin film and an application thereof.

### BACKGROUND

In indium (In)-based transparent conductive metal oxide (TCO) thin film systems widely used at present, since indium ions (In³⁺) have a relatively large ionic radius, the In—In bond orbital overlap is larger, so that its 5s orbit becomes an efficient carrier transport channel. The most mature and widely used TCO material is an indium tin oxide (ITO) (In₂O₃:SnO₂=90:10 wt. %) thin film, in which In³⁺ provides an efficient conductive channel, and Sn⁴⁺ may serve as a carrier provided to a donor, and reduce the distortion of an In—O bond. However, in the ITO system, due to the lower bond breaking energy of In—O after indium bonding with oxygen, there are a large number of oxygen vacancy defects in a pure indium oxide (In₂O₃) film. Oxygen vacancies, as a typical carrier donor, may lead to the excessively high carrier concentration. The excessively high carrier concentration may cause surface plasma effects, so that the absorption of the ITO thin film is larger in the infrared band. Therefore, existing applications of TCO materials need to improve the electron mobility and reduce the carrier concentration as much as possible.

### SUMMARY

In order to overcome deficiencies of existing technologies, a first purposes of the present application is to provide a transparent conductive metal oxide thin film, it could effectively control the oxygen vacancy concentration in an In₂O₃ thin film by using rare earth ions in a rare earth oxide to have the lower electronegativity and using an ionic bond Ln-O formed with oxygen ions to have the higher bond breaking energy. In addition, the rare earth metal ions and indium ions have an equivalent ionic radius, so it is easier to maintain the crystal structure of an indium oxide when being doped, sufficient overlap of a 5s orbit of indium is guaranteed, defect scattering caused by structure mismatch could be reduced, and therefore, the high mobility characteristics thereof could be kept better.

A second purpose of the present application is to provide an application of the transparent conductive oxide thin film.

The first purpose of the present application is achieved by adopting the following technical schemes.

A transparent conductive metal oxide thin film is disclosed, and the metal oxide is: a transparent conductive material of (In₂O₃)ₓ(MO)_{y}(ReO)_{z} formed by doping a small amount of a rare earth oxide ReO into an indium-containing metal oxide MO—In₂O₃ as a photon-generated carrier conversion center, herein x+y+z=1, 0.8≤x<0.9999, 0≤y<0.2, 0.0001≤z≤0.1.

Herein, the rare earth oxide ReO is one of ytterbium oxide, europium oxide, cerium oxide, praseodymium oxide and terbium oxide or any combinations of more than two materials.

In the metal oxide MO, M is one of stannum (Sn), bismuth (Bi), titanium (Ti), zirconium (Zr), hafnium (Hf), tantalum (Ta), wolfram (W), niobium (Nb), and molybdenum (Mo) or any combinations of more than two materials. Namely, the transparent conductive oxide thin film provided by the present application is a composite conductive thin film based on the indium oxide, it obtains the higher mobility by introducing the rare earth oxide, and its carrier concentration is controlled as well. The rare earth ions in the rare earth oxide have the lower electronegativity, and the ionic bond Ln-O formed with the oxygen ions has the higher bond breaking energy. Therefore, it is possible to effectively control the oxygen vacancy concentration in the In₂O₃ thin film. The optional material of the rare earth oxide ReO is one of ytterbium oxide, europium oxide, cerium oxide, praseodymium oxide, and terbium oxide or any combinations of more than two materials, which serves as a carrier concentration control agent. Herein, Yb²⁺ and Eu²⁺ ions in the ytterbium oxide and europium oxide have full and half-full 4f electronic orbits respectively. Therefore, its divalent ions have the lower energy in oxides compared to trivalent ions. Meanwhile, since changes in bond breaking enthalpy (ΔHf298) of Yb—O and Eu—O are 715.1 kJ/mol and 557.0 kJ/mol respectively, which are much greater than the bond breaking energy of In—O, the oxygen vacancy concentration could be effectively controlled. The oxygen ions in the cerium oxide, praseodymium oxide, and terbium oxide have the valence change possibility of +3 and +4 valences. In oxide, when In³⁺ ions are replaced with doping, the carrier concentration may be significantly reduced. The bond breaking energies of Ce—O, Pr—O, and Tb—O bonds are higher, and all greater than 759 kJ/mol. So the cerium oxide, praseodymium oxide, and terbium oxide have the stronger ability to control the carrier concentration. Based on the above characteristics, the introduction of ReO may effectively control the oxygen vacancies of the oxide thin films in high-In systems. In addition, the indium oxide is prone to generate lattice distortion in the preparation process, and the introduction of the rare earth oxide could effectively suppresses the distortion; moreover, the rare earth metal ions and indium ions have the equivalent ionic radius, it is easier to maintain the crystal structure of the indium oxide when being doped, the sufficient overlap of the 5s orbit of indium is guaranteed, the defect scattering caused by the structure mismatch could be reduced, and therefore its high mobility characteristics may be also kept better.

At the same time, the ReO rare earth oxide introduced could serve as the photon-generated charge conversion center. The material selection utilizes the electronic structure characteristics of the 4f orbit in the rare earth ions, and it may form an efficient charge conversion center with the 5s orbit of the indium ions. Under the positive bias, the rare earth ions are in a stable low-energy state. Due to the modulation action of Fermi energy, the thin film has the higher carrier concentration, and it could effectively shield the carrier scattering effect caused by the conversion center, thus it does not have the apparent impact on the electrical properties and the like of devices. Under the negative bias, the electron orbits in the rare earth element 4f are coupled with the 5s orbit of indium, and the rare earth ions are in an unstable activation state. The photon-generated carrier is returned to a “ground state” in the form of non-radiative transition by its coupling orbit; meanwhile, the activation center is reactivated. Therefore, the conversion center may provide a fast recombination channel for the photon-generated carrier, and it is avoided from impacting on the stability of the thin film.

Further, the transparent conductive oxide thin film is a crystal structure of bixbyite.

Preferably, 0.0001≤z≤0.005.

More preferably, 0.0009≤z≤0.001.

Further, the carrier mobility of the transparent conductive oxide thin film is 50˜200 cm²/Vs, and the carrier concentration is 1×10¹⁹˜5×10²¹ cm⁻³. Preferably, the carrier mobility of the transparent conductive oxide thin film is 120˜200 cm²/Vs, and the carrier concentration is 1×10¹⁹˜6×10²⁰ cm⁻³.

Further, the transparent conductive oxide thin film is prepared by any one of a physical vapor deposition process, a chemical vapor deposition process, an atomic layer deposition process, a laser deposition process, a reactive plasma deposition process, and a solution process.

The second purpose of the present application is achieved by adopting the following technical schemes.

An application of the above transparent conductive oxide thin film in a solar cell, a display panel, or a detector is disclosed.

Compared to the existing technologies, the beneficial effects of the present application are as follows.

By selecting a doping strategy, the present application achieves the control of the carrier concentration and improves the mobility by introducing the rare earth oxide material into the indium-based metal oxide, and by using the rare earth ions in the rare earth oxide to have the lower electronegativity and using the ionic bond Ln-O formed with the oxygen ions to have the higher bond breaking energy, it could effectively control the oxygen vacancy concentration in the In₂O₃ thin film. In addition, the rare earth ions and indium ions have the equivalent ionic radius, and the defect scattering caused by the structure mismatch could be reduced, so it could maintain the high mobility characteristics better.

The present application introduces the doped rare earth oxide into the indium-containing metal oxide to form the high-performance transparent conductive thin film. Since the rare earth oxide has the extremely high oxygen bond breaking energy, the carrier concentration in the oxide could be effectively controlled, and the transmittance in the infrared band could be improved, so that it is more suitable for the application in the solar cell, the display panel, or the detector.

### BRIEF DESCRIPTION OF THE DRAWINGS

FIG. 1 is a transmittance spectrum of TCO1 of a transparent conductive thin film in Embodiment 6; and

FIG. 2 is a transmittance spectrum of TCO2 of the transparent conductive thin film in Embodiment 6.

### DETAILED DESCRIPTION OF THE EMBODIMENTS

The present application is further described below in combination with drawings and specific implementation modes. It should be noted that, without conflicting, the various embodiments or technical features described below may be combined arbitrarily to form new embodiments.

The following are specific embodiments of the present application. Raw materials, devices and the like used in the following embodiments may be obtained by means of purchase, except for special limitations.

### Embodiment 1: Cerium Oxide-Doped Indium Tin Oxide Transparent Conductive Thin Film

A group of transparent conductive oxide thin films is provided, and the material of this group of the transparent conductive oxide thin films is: a transparent conductive material of cerium oxide-doped indium tin oxide (Ce:ITO) formed by doping a cerium oxide into an indium tin oxide (ITO) as a charge conversion center. This group of the transparent conductive oxide thin films is prepared by a solution process.

Herein, for the general formula of oxide ratio (InO_{1.5})ₓ(MO)_{y}(ReO)_{z}, MO is SnO₂, and the ReO oxide is CeO₂. In the composed oxide (InO_{1.5})ₓ(SnO₂)_{y}(CeO₂)_{z}, x=0.97270, y=0.0264, and z=0.0009. But it is not limited to the above proportion, in other embodiments, x=0.96000, y=0.03908, z=0.00092, or x=0.900, y=0.095, z=0.0050, or x=0.9200, y=0.07999, z=0.00001, and it is not repeatedly described here.

The carrier mobility of the transparent conductive oxide thin film is 123 cm²/Vs, and the carrier concentration is 9.1×10¹⁹ cm⁻³.

### Embodiment 2: Ytterbium Oxide-Doped Indium Titanium Oxide Transparent Conductive Thin Film

A group of transparent conductive oxide thin films is provided, and the material of this group of the transparent conductive oxide thin films is: a transparent conductive material of ytterbium oxide-doped indium titanium oxide (Yb:ITiO) formed by doping an ytterbium oxide into an indium titanium oxide (ITiO) as a charge conversion center. This group of the transparent conductive oxide thin films is prepared by a magnetron sputtering process.

Herein, for the general formula of oxide ratio (InO_{1.5})ₓ(MO)_{y}(ReO)_{z}, MO is TiO₂, and the ReO oxide is Yb₂O₃. In the composed oxide (InO_{1.5})ₓ(TiO₂)_{y}(YbO_{1.5})_{z}, x=0.97943, y=0.01959, and z=0.00098. But it is not limited to the above proportion, in other embodiments, x=0.98000, y=0.01950, z=0.00050, or x=0.99000, y=0.00500, z=0.00500, or x=0.9200, y=0.07999, z=0.00001, and it is not repeatedly described here.

The carrier mobility of the transparent conductive oxide thin film is 186 cm²/Vs, and the carrier concentration is 3.6×10²⁰ cm⁻³.

### Embodiment 3: Europium Oxide-Doped Indium Zirconium Oxide Transparent Conductive Thin Film

A group of transparent conductive oxide thin films is provided, and the material of this group of the transparent conductive oxide thin films is: a transparent conductive material of europium oxide-doped indium zirconium oxide (Eu:IZrO) formed by doping a europium oxide into an indium zirconium oxide (IZrO) as a charge conversion center. This group of the transparent conductive oxide thin films is prepared by an atomic layer deposition process.

Herein, for the general formula of oxide ratio (InO_{1.5})ₓ(MO)_{y}(ReO)_{z}, MO is ZrO₂, and the ReO oxide is Eu₂O₃. In the composed oxide (InO_{1.5})ₓ(ZrO₂)_{y}(EuO_{1.5})_{z}, x=0.93943, y=0.05959, and z=0.00098. But it is not limited to the above proportion, in other embodiments, x=0.98000, y=0.01950, z=0.00050, or x=0.97000, y=0.02800, z=0.00200, or x=0.9900, y=0.00999, z=0.00001, and it is not repeatedly described here.

The carrier mobility of the transparent conductive oxide thin film is 135 cm²/Vs, and the carrier concentration is 8.8×10¹⁹ cm⁻³.

### Embodiment 4: Praseodymium Oxide-Doped Indium Oxide Transparent Conductive Thin Film

A group of transparent conductive oxide thin films is provided, and the material of this group of the transparent conductive oxide thin films is: a transparent conductive material of praseodymium oxide-doped indium oxide (IPrO) formed by doping a praseodymium oxide into an indium oxide (In₂O₃) as a charge conversion center. This group of the transparent conductive oxide thin films is prepared by a reactive plasma deposition process.

Herein, for the general formula of oxide ratio (InO_{1.5})ₓ(MO)_{y}(ReO)_{z}, MO is not contained, namely y=0; and the ReO oxide is Pr₂O₃. In the composed oxide (InO_{1.5})ₓ(PrO_{1.5})_{z}, x=0.9000, and z=0.1000. But it is not limited to the above proportion, in other embodiments, x=0.98000, z=0.0200, or x=0.99000, z=0.01000, or x=0.9990, z=0.00100, and it is not repeatedly described here.

The carrier mobility of the transparent conductive oxide thin film is 173 cm²/Vs, and the carrier concentration is 5.6×10²⁰ cm⁻³.

### Embodiment 5: Terbium Oxide-Doped Indium Oxide Transparent Conductive Thin Film

A group of transparent conductive oxide thin films is provided, and the material of this group of the transparent conductive oxide thin films is: a transparent conductive material of terbium oxide-doped indium oxide (ITbO) formed by doping a terbium oxide into an indium oxide (In₂O₃) as a charge conversion center. This group of the transparent conductive oxide thin films is prepared by a magnetron sputtering process.

Herein, for the general formula of oxide ratio (InO_{1.5})ₓ(MO)_{y}(ReO)_{z}, MO is not contained; and the ReO oxide is Tb₂O₃. In the composed oxide (InO_{1.5})ₓ(TbO_{1.5})_{z}, x=0.9800, y=0, and z=0.0200. But it is not limited to the above proportion, in other embodiments, x=0.9900, y=0, z=0.0100, or x=0.9850, z=0.0150, or x=0.9990, y=0, z=0.0010, and it is not repeatedly described here.

The carrier mobility of the transparent conductive oxide thin film is 148 cm²/Vs, and the carrier concentration is 9.4×10¹⁹ cm⁻³.

### Embodiment 6: Heterojunction Solar Cell

In this embodiment, an n-type monocrystalline silicon wafer is used as a substrate, and intrinsic a-Si and p-type a-Si with a thickness of 10 nm are deposited sequentially on the n-type silicon wafer after a cleaning process, to form a p-n heterojunction, and then a transparent conductive film TCO1 is deposited on the p-n heterojunction. On the back surface of the silicon wafer, an intrinsic a-Si film and an n-type a-Si film with a thickness of 10 nm are deposited sequentially, and then a transparent conductive film TCO2 is deposited on the n-type a-Si film. Finally, on TCO1 and TCO2, conductive silver paste is prepared as a collector electrode by using a screen printing technology respectively.

Herein the TCO1 material is an ytterbium oxide-doped indium oxide transparent conductive material, and is prepared by a reactive plasma deposition process. In the composed oxide (InO_{1.5})ₓ(YbO_{1.5})_{z}, x=0.9000, and z=0.1000.

The specific preparation conditions thereof are as follows.

The target material is a cylindrical ceramic target material, and the relative density of the target material is about 65%;
the substrate is not heated, and a dual-gun plasma source is used, namely two target are used for film deposition simultaneously;
the oxygen content in the chamber is 20%, namely O₂/(Ar+O₂)=20%;
the chamber air pressure is 0.3 Pa; and
the voltage applied to the ion source is 70 V, 175A.

Herein the TCO2 material is an ytterbium oxide-doped indium oxide transparent conductive material, and is prepared by a magnetron sputtering deposition process. In the composed oxide (InO_{1.5})ₓ(YbO_{1.5})_{z}, x=0.98000, and z=0.0200.

The specific preparation conditions thereof are as follows.

The target material is a linear ceramic target material, and the relative density of the target material is about 99%;
it is deposited by using a single sputtering target;
the substrate is not heated;
the oxygen content in the chamber is 1.0%, namely O₂/(Ar+O₂)=1.0%;
the chamber air pressure is 0.3 Pa; and
a pulsed direct current (DC) power supply is used, and the sputtering power is 2 kw.

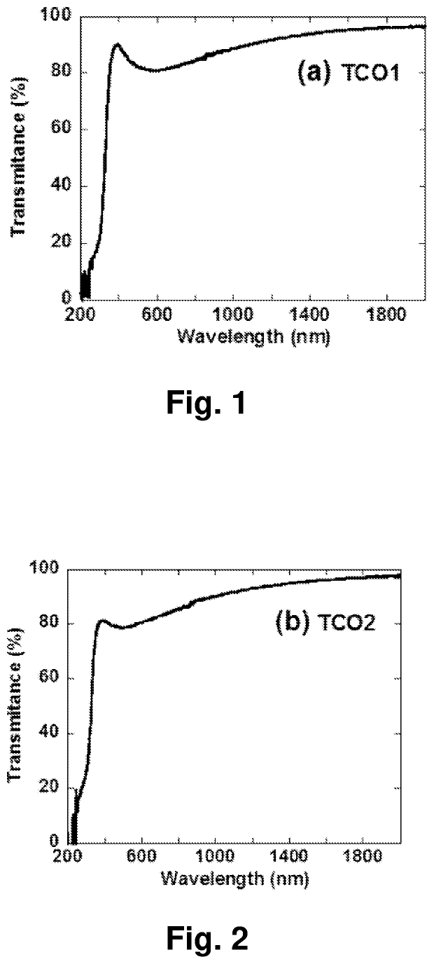

Meanwhile, in this embodiment, a reference thin film is prepared simultaneously on a blank quartz substrate. The Hall properties of the prepared transparent conductive film are shown in Table 1, and the transmittance spectra of the thin films are shown in FIGS. 1 and 2.

TABLE 1
Hall property parameters of transparent conductive thin films

| Material | Carrier concentration (cm⁻³) | Carrier mobility (cm²/Vs) |
|---|---|---|
| TCO1 | 1.2 × 10²⁰ | 169 |
| TCO2 | 1.5 × 10²⁰ | 142 |

In the above embodiments, the transparent conductive film TCO1 and the transparent conductive film TCO2 are not limited to the materials mentioned above. This material may also be composed of the transparent conductive thin film in Embodiments 1-5 recorded in the present application, and it is not repeatedly described here.

### Embodiment 7: Display Panel

A display panel is provided, and includes the transparent conductive thin film in Embodiments 1-5 above, and this thin film is used for an organic light emitting diode (OLED) anode in the display panel.

### Embodiment 8: Detector

A detector is provided, and includes the transparent conductive thin film in Embodiments 1-5 above, and this thin film is used to drive a detection unit of the detector.

The above embodiments are preferred implementation modes of the present application, but the implementation modes of the present application are not limited by the above embodiments. Any other changes, modifications, replacements, combinations, and simplifications made that do not deviate from the spirit and principles of the present application should be equivalent substitution modes, and are all included in the scope of protection of the present application.

1. A transparent conductive metal oxide thin film, wherein the metal oxide is: a transparent conductive material of (In₂O₃)ₓ(MO)_{y}(ReO)_{z} formed by doping a small amount of a rare earth oxide ReO into an indium-containing metal oxide MO—In₂O₃ as a photon-generated carrier conversion center, wherein x+y+z=1, 0.8≤x<0.9999, 0≤y<0.2, 0.0001≤z≤0.1.

2. The transparent conductive oxide thin film as claimed in claim 1, characterized in that in the MO, M is one of stannum (Sn), bismuth (Bi), titanium (Ti), zirconium (Zr), hafnium (Hf), tantalum (Ta), wolfram (W), niobium (Nb), and molybdenum (Mo) or any combinations of more than two materials.

3. The transparent conductive oxide thin film as claimed in claim 1, characterized in that the rare earth oxide ReO is one of ytterbium oxide, europium oxide, cerium oxide, praseodymium oxide, and terbium oxide or any combinations of more than two materials.

4. The transparent conductive oxide thin film as claimed in claim 1, characterized in that the transparent conductive oxide thin film is a crystal structure of bixbyite.

5. The transparent conductive oxide thin film as claimed in claim 1, characterized in that 0.0001≤z≤0.005.

6. The transparent conductive oxide thin film as claimed in claim 5, characterized in that 0.0009≤z≤0.001.

7. The transparent conductive oxide thin film as claimed in claim 1, characterized in that the carrier mobility of the transparent conductive oxide thin film is 50˜200 cm²/Vs, and the carrier concentration is 1×10¹⁹˜5×10²¹ cm⁻³.

8. The transparent conductive oxide thin film as claimed in claim 7, characterized in that the carrier mobility of the transparent conductive oxide thin film is 120˜200 cm²/Vs, and the carrier concentration is 1×10¹⁹˜6×10²⁰ cm⁻³.

9. The transparent conductive oxide thin film as claimed in claim 7, characterized in that the transparent conductive oxide thin film is prepared by any one of a physical vapor deposition process, a chemical vapor deposition process, an atomic layer deposition process, a laser deposition process, a reactive plasma deposition process, and a solution process.
